(19) United States
(12) Patent Application Publication
(10) Pub. No.: US 2024/0276804 A1
(43) Pub. Date: Aug. 15, 2024

(54) DISPLAY DEVICE

(71) Applicant: Samsung Display Co., LTD., Yongin-si (KR)

(72) Inventor: CHUNGI YOU, Yongin-si (KR)

(21) Appl. No.: 18/427,741

(22) Filed: Jan. 30, 2024

(30) Foreign Application Priority Data
Feb. 15, 2023 (KR) 10-2023-0020236

(51) Int. Cl. H10K 59/131; H10K 59/80

(52) U.S. Cl. CPC H10K 59/131; H10K 59/878

(57) ABSTRACT

A display device includes a substrate including a semiconductor chip, and having a display region, and a peripheral region adjacent to the display region, pixels above the substrate in the display region, and a crack detection line above the substrate in the peripheral region.

### CROSS-REFERENCE TO RELATED APPLICATION

This application claims priority to, and the benefit of, Korean Patent Application No. 10-2023-0020236 filed on Feb. 15, 2023, in the Korean Intellectual Property Office (KIPO), the entire disclosure of which is incorporated by reference herein.

### BACKGROUND

### 1. Field

Embodiments relate to a display device with improved display quality.

### 2. Description of the related art

Portable electronic devices, such as mobile phones, navigation devices, digital cameras, e-books, and portable game consoles may include liquid crystal displays (LCDs), organic light-emitting displays (OLEDs), or the like. A display device used in such the portable electronic device may have flexible characteristics. As the display device has the flexible characteristics, portability of the display device may be improved.

Generally, a plurality of display panels are formed on one mother substrate, and the plurality of display panels may be separated into individual display panels through a scribing process. In the process of cutting the mother substrate, cracks may occur on the display panel.

In addition, after manufacturing the display device in a form of a flat panel, the display device may be bent, rolled, or folded. At this time, cracks due to stress may occur in the display panel.

When cracks occur in the display panel, defects may occur in the display device as the cracks propagate. For example, the display device might not be driven correctly, or a dark spot may occur due to penetration of moisture, or the like.

### SUMMARY

The disclosure may provide a display device.

A display device according to one or more embodiments of the disclosure includes a substrate including a semiconductor chip, and having a display region, and a peripheral region adjacent to the display region, pixels above the substrate in the display region, and a crack detection line above the substrate in the peripheral region.

The crack detection line may have a multi-layer structure.

The crack detection line may include a first metal layer, and a second metal layer above the first metal layer.

The first metal layer may include a reflective metal material, wherein the second metal layer includes a transparent conductive material or a translucent conductive material.

The crack detection line may further include a third metal layer above the second metal layer.

The third metal layer may include a chemical-resistant metal material.

The substrate may further include a first blocking layer in the peripheral region, and a second blocking layer in the peripheral region adjacent to the first blocking layer.

The crack detection line may be above the first blocking layer.

The crack detection line may be above the second blocking layer.

The crack detection line may be above both the first blocking layer and the second blocking layer.

A display device according to one or more embodiments of the disclosure includes a substrate having a display region, and a peripheral region adjacent to the display region, and having a width of about tens of micrometers or less, pixels above the substrate in the display region, and a crack detection line above the substrate in the peripheral region.

The crack detection line may have a multi-layer structure.

The crack detection line may include a first metal layer, and a second metal layer above the first metal layer.

The first metal layer may include a reflective metal material, wherein the second metal layer includes a transparent conductive material or a translucent conductive material.

The crack detection line may further include a third metal layer above the second metal layer.

The third metal layer may include a chemical-resistant metal material.

The substrate may further include a first blocking layer in the peripheral region, and a second blocking layer in the peripheral region adjacent to the first blocking layer.

The crack detection line may be above the first blocking layer.

The crack detection line may be above the second blocking layer.

The crack detection line may be above both the first blocking layer and the second blocking layer.

In a display device according to one or more embodiments, the display device may include a substrate, a plurality of pixels, and a crack detection line. The substrate may include a semiconductor chip. A display region, and a peripheral region adjacent to the display region, may be defined on the substrate. The plurality of pixels may be located on the substrate in the display region. The crack detection line may be located on the substrate in the peripheral region. As the display device includes the crack detection line, a crack in the display device may be detected.

### BRIEF DESCRIPTION OF THE DRAWINGS

FIG. 1 is a plan view of a display device according to one or more embodiments of the disclosure.

FIG. 2 is a view illustrating pixels included in the display device of FIG. 1.

FIG. 3 is a cross-sectional view taken along the line I-I′ of FIG. 1.

FIG. 4 is a cross-sectional view taken along the line II-II′ of FIG. 1.

FIG. 5 is a view illustrating an organic layer according to one or more embodiments of FIG. 4.

FIG. 6 is a view illustrating the organic material layer according to one or more other embodiments of FIG. 4.

FIG. 7 is a cross-sectional view taken along the line III-III′ of FIG. 1.

FIGS. 8, 9, and 10 are enlarged cross-sectional views illustrating a crack detection line included in the display device of FIG. 1.

FIG. 11 is view illustrating one or more embodiments in which the display device of FIG. 1 is implemented as smart glasses.

FIG. 12 is a view illustrating one or more embodiments in which the display device of FIG. 1 is implemented as a head mounted display device.

FIGS. 13, 14, 15, 16, 17, and 18 are views illustrating a method of manufacturing the display device of FIG. 1.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The present disclosure covers all modifications, equivalents, and replacements within the idea and technical scope of the present disclosure. Further, each of the features of the various embodiments of the present disclosure may be combined or combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled,” or “directly on,” refers to one component directly connecting or coupling another component, or being on another component, without an intermediate component. In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” the another portion but also a case where there is further still another portion between the portion and the another portion. Meanwhile, other expressions describing relationships between components such as “between” and “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z” and “at least one selected from the group consisting of X, Y, and Z” may be construed as X only, Y only, Z only, any combination of two or more of X, Y, and Z, such as, for instance, XYZ, XYY, YZ, and ZZ, or any variation thereof. Similarly, the expression such as “at least one of A and B” may include A, B, or A and B. As used herein, “or” generally means “and/or,” and the term “and/or” includes any and all combinations of one or more of the associated listed items. For example, the expression such as “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

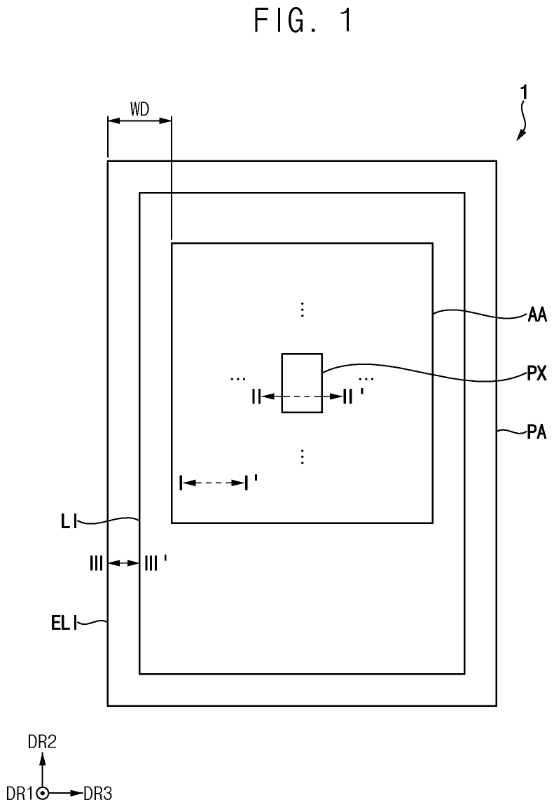

FIG. 1 is a plan view of a display device according to one or more embodiments of the disclosure.

Referring to FIG. 1, a display region AA and a peripheral region PA may be defined in a display device 1 according to one or more embodiments of the disclosure. The display device 1 may have various shapes in a plan view. For example, the display device 1 may have a rectangular shape in the plan view. In this case, a plane may be defined by a second direction DR2 and a third direction DR3. The third direction DR3 may cross the second direction DR2. For example, the display device 1 may have the rectangular shape having a long side in the second direction DR2, and a short side in the third direction DR3.

The display device 1 may include light-emitting diodes having various sizes. For example, the display device 1 may be a microdisplay. The microdisplay may include a subminiature light-emitting diode (or a micro-light-emitting diode).

For example, the display device 1 may be a self-luminous (emissive) microdisplay. The self-luminous microdisplay may generate light, such that the self-luminous microdisplay may omit a separate light source. However, the disclosure is not limited thereto.

As another example, the display device 1 may be a reflective microdisplay. The reflective microdisplay may include a light source on a front side of a panel of the microdisplay. The reflective microdisplay may employ a scheme of modulating an external light while varying characteristics (a refractive index, a transmittance, etc.) of a reflective surface to reflect and view an image.

As still another example, the display device 1 may be a transmissive microdisplay. The transmissive microdisplay may include a light source located on a rear side of a panel of the microdisplay. The transmissive microdisplay may have the same structure as a liquid crystal display (LCD).

The display region AA may be an area that displays an image. For example, the image may be displayed along, or in, a first direction DR1. Each of the first direction DR1, the second direction DR2, and the third direction DR3 may cross each other. For example, Each of the first direction DR1, the second direction DR2, and the third direction DR3 may be substantially perpendicular each other.

A planar shape of the display region AA may be a rectangle with rounded corners. However, the disclosure is not limited thereto. For example, the display region AA may have various planar shapes, such as a circular shape, an elliptical shape, a polygonal shape, or the like.

A plurality of pixels PX may be arranged in the display region AA. For example, the plurality of pixels PX may be located on a substrate.

The substrate may include a base substrate and an epitaxial layer. For example, the substrate may have a structure in which the epitaxial layer is stacked on the base substrate. However, the disclosure is not limited thereto. For example, the substrate may be a silicon substrate, a gallium arsenide substrate, a silicon germanium substrate, a ceramic substrate, a quartz substrate, a glass substrate for a display, a semiconductor on insulator (SOI) substrate, or the like.

In addition, the substrate may have a single-layer structure or a multi-layer structure. For example, the substrate may have a structure in which insulating layers are stacked on the silicon substrate.

The plurality of pixels PX may be located in a matrix form. For example, the pixels PX may be repeatedly arranged in the third direction DR3 and the second direction DR2 in the plan view. For example, the plurality of pixels PX may be defined as a minimum light-emitting unit capable of displaying a white light.

A plurality of signal lines may be located in the display region AA. For example, scan lines, data lines, or the like may be located in the display region AA. For example, the scan lines may extend in the second direction DR2, and may be spaced apart from each other in the third direction DR3. The data lines may extend in the third direction DR3 and may be spaced apart from each other in the second direction DR2.

The signal lines may be connected to respective ones of the pixels PX. For example, each of the pixels PX may be connected to at least one of the scan lines and at least one of the data lines. For example, each of the pixels PX may receive a scan signal from a corresponding scan line, and may receive a data signal from a corresponding data line. Accordingly, the display device 1 may display the image in the first direction DR1.

The peripheral region PA may be adjacent to the display region AA. When the display device 1 is the micro-display, a width WD of the peripheral region PA may be about several tens of micrometers or less. For example, the width WD of the peripheral region PA may be about 10 micrometers.

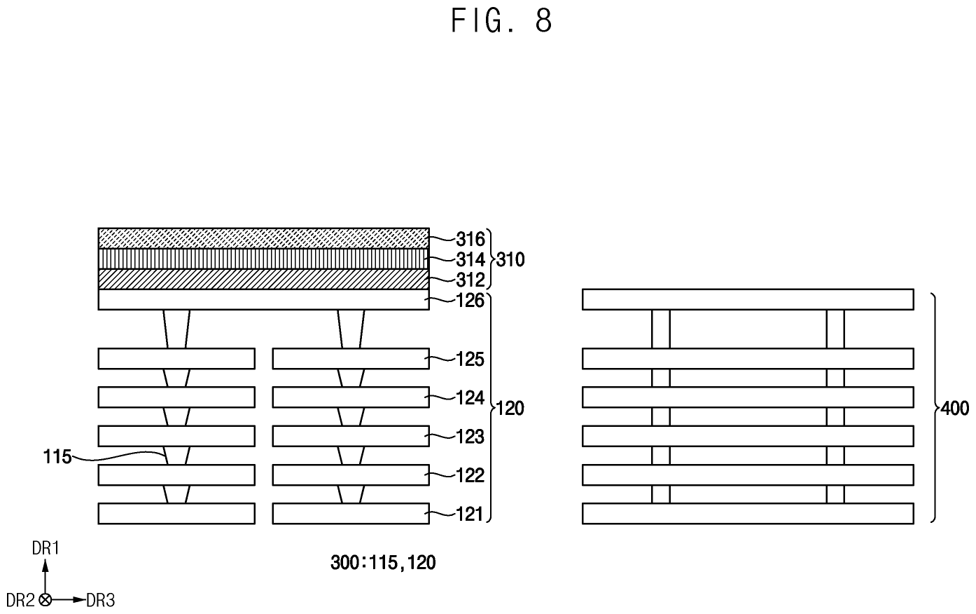

A plurality of lines LI may be located in the peripheral region PA. For example, the plurality of lines LI may include a power line, a test line (e.g., crack detection lines 310, 320, and 330 of FIGS. 8, 9, and 10), or the like.

The power line may be connected to each of the plurality of pixels PX. Accordingly, the power line may transmit a power voltage to each of the plurality of pixels PX.

In the plan view, the test line may be positioned between the power line and an outer line EL1 of the display device 1 (i.e., outer border of the display device 1). A crack in the display device 1 may be detected by the test line. A detailed description of the test line will be described later with reference to FIG. 8.

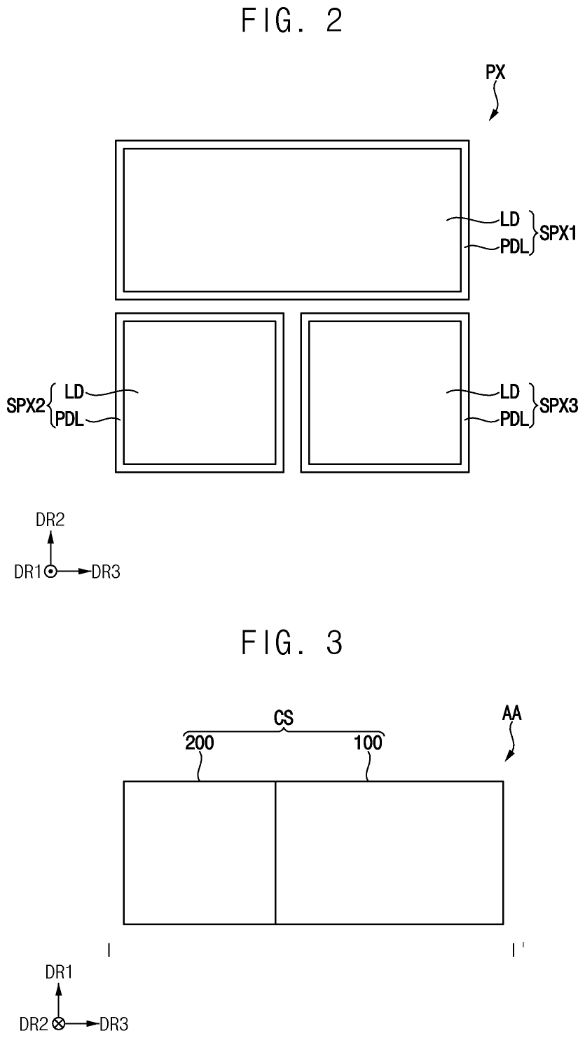

FIG. 2 is a view illustrating pixels included in the display device of FIG. 1.

Referring to FIGS. 1 and 2, each of the pixels PX may include a first sub-pixel region SPX1, a second sub-pixel region SPX2, and a third sub-pixel region SPX3. Although each of the pixels PX has been shown in FIG. 2 as including the first sub-pixel region SPX1, the second sub-pixel region SPX2, and the third sub-pixel region SPX3, the disclosure is not limited thereto. For example, each of the pixels PX may include at least four sub-pixel regions.

A light-emitting diode LD may be located in each of the first, second, and third sub-pixel regions SPX1, SPX2, and SPX3, and be surrounded by the pixel defining layer PDL. In one or more embodiments, the light-emitting diode LD may emit a first light. For example, the light-emitting diode LD may emit the white light.

The first light may be converted into second light while passing through a color filter layer (e.g., a color filter layer CF of FIG. 4) overlapping the first sub-pixel region SPX1. For example, the second light may be red light.

The first light may be converted into third light while passing through the color filter layer (e.g., the color filter layer CF of FIG. 4) overlapping the second sub-pixel region SPX2. For example, the third light may be green light. The first light may be converted into fourth light while passing through the

color filter layer (e.g., the color filter layer CF of FIG. 4) overlapping the third sub-pixel region SPX3. For example, the fourth light may be blue light.

However, the disclosure is not limited thereto. For example, each of the second light, the third light, and the fourth light may be light of various colors.

In one or more other embodiments, the light-emitting diodes LD may emit a light having one color among a red color, a blue color, and a green color. However, the disclosure is not limited thereto. For example, the light-emitting diodes LD may emit a light having one color among a yellow color, a cyan color, and a magenta color.

The lights emitted from the first sub-pixel region SPX1, the second sub-pixel region SPX2, and the third sub-pixel region SPX3 may be combined to emit lights having various colors.

The light-emitting diode LD may have various planar shapes. In one or more embodiments, the light-emitting diode LD may have a polygonal shape on the plane. For example, the light-emitting diode LD may have a quadrangular shape on the plane. However, the disclosure is not limited thereto. For example, the light-emitting diode LD may have various shapes, such as a circular shape, an elliptical shape, a polygonal shape other than a quadrangular shape, or the like.

In one or more embodiments, the first sub-pixel region SPX1, the second sub-pixel region SPX2, and the third sub-pixel region SPX3 may have mutually different areas in the plan view. For example, when the red light is emitted from the first sub-pixel region SPX1, an area of the first sub-pixel region SPX1 may be larger than an area of the second sub-pixel region SPX2. In addition, the area of the first sub-pixel region SPX1 may be larger than an area of the third sub-pixel region SPX3. In one or more other embodiments, each of the sub-pixel regions SPX1, SPX2, and SPX3 may have substantially a same area in the plan view.

The first sub-pixel region SPX1, the second sub-pixel region SPX2, and the third sub-pixel region SPX3 may have various arrangements in the plan view. For example, the first sub-pixel region SPX1 may be arranged in a row that is different from a row in which the second sub-pixel region SPX2 is arranged. In addition, the first sub-pixel region SPX1 may be positioned in a row that is different from a row in which the third sub-pixel region SPX3 is positioned. The second sub-pixel region SPX2 and the third sub-pixel region SPX3 may be positioned in the same row. However, the disclosure is not limited thereto.

In one or more embodiments, the display device 1 may be the micro-display. In this case, each of the plurality of sub-pixels may have a size of about several to about several tens of micrometers.

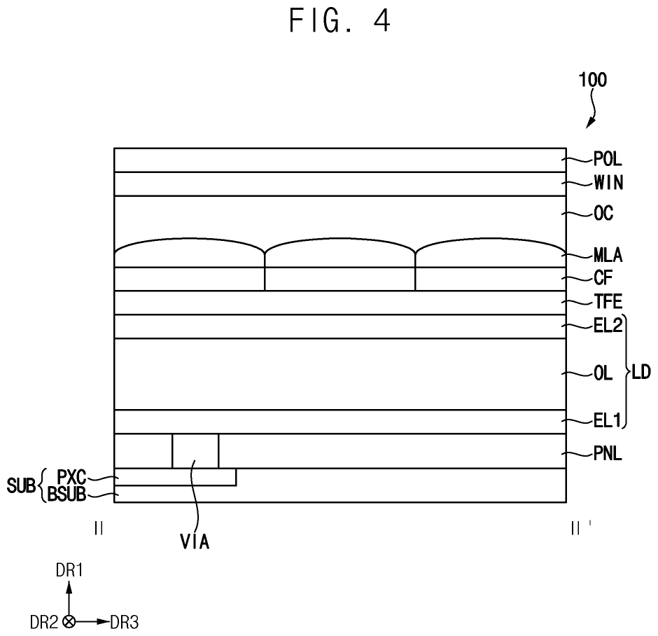

FIG. 3 is a cross-sectional view taken along the line I-I′ of FIG. 1.

Referring to FIGS. 1 and 3, the display device 1 according to one or more embodiments of the disclosure may include a chip structure CS. The chip structure CS may include a chip 100 and a guard ring 200.

The chip 100 and the guard ring 200 may be located on the substrate in the display region AA. In one or more embodiments, the chip 100 may be a semiconductor chip. For example, the semiconductor chip may be a memory chip, a logic chip, or the like.

When the semiconductor chip is the logic chip, the logic chip may be designed in various ways considering operations to be formed. When the semiconductor chip is the memory chip, the memory chip may be a non-volatile memory chip. For example, the memory chip may be a flash memory chip. For example, the memory chip may be any one of a NAND flash memory chip and/or a NOR flash memory chip. However, the disclosure is not limited thereto. For example, the memory chip may be a phase-change random access memory, magneto-resistive random-access memory, resistive random-access memory, or the like.

In addition, the semiconductor chip may include various elements. For example, the semiconductor chip may include various active devices and passive devices. For example, the semiconductor chip may include a MOSFET, such as a CMOS transistor, a large-scale integration (LSI) system, an image sensor, such as a CMOS image sensor (CIS), a microelectromechanical system (MEMS), or the like.

The guard ring 200 may be adjacent to the chip 100. For example, the guard ring 200 may surround a side surface of the chip 100 on the plane. In FIG. 3, it has been described that the guard ring 200 is located in a direction opposite to the third direction DR3 from the chip 100, but the disclosure is not limited thereto. The guard ring 200 may be located in the first direction DR1, the opposite direction to the first direction DR1, and/or the third direction DR3 from the chip 100. Alternatively, the guard ring 200 may be located on only a portion of the side surface of the chip 100. The guard ring 200 may include a metal material. For example, the guard ring 200 may include a metal seal.

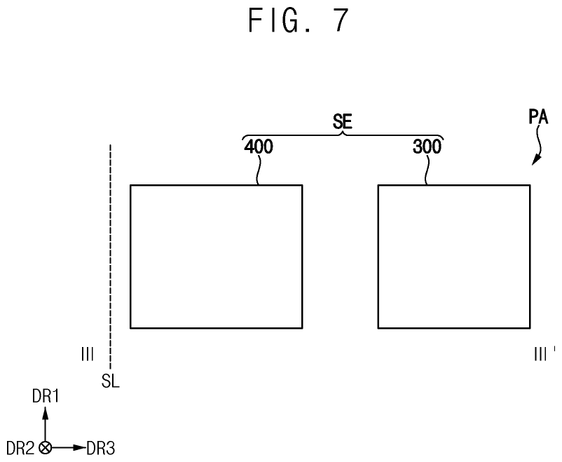

A wafer may be separated into individual chips 100 along a scribing line (e.g., a scribing line SL of FIG. 7). During this sawing process, the crack may occur in the wafer.

The guard ring 200 may reduce or prevent the likelihood of the crack that may occur in the sawing process from propagating to the chip 100, or may reduce or prevent foreign substances (e.g., ionic contaminants) from being transferred to the chip 100 through the crack.

Surge currents may be defined as currents that pass along a circuit and have characteristics of rapidly increasing and slowly decreasing. The surge current may dissipate thermal energy to damage or destroy a device (e.g., the light-emitting diode LD of FIG. 2).

The guard ring 200 may provide a low-resistance path for the surge current. The guard ring 200 may reduce or prevent destruction of, or damage to, the device due to receiving and discharging abnormal EMI (Electro Magnetic Interference) and ESD (Electro Static Discharge), such as the surge current to the outside.

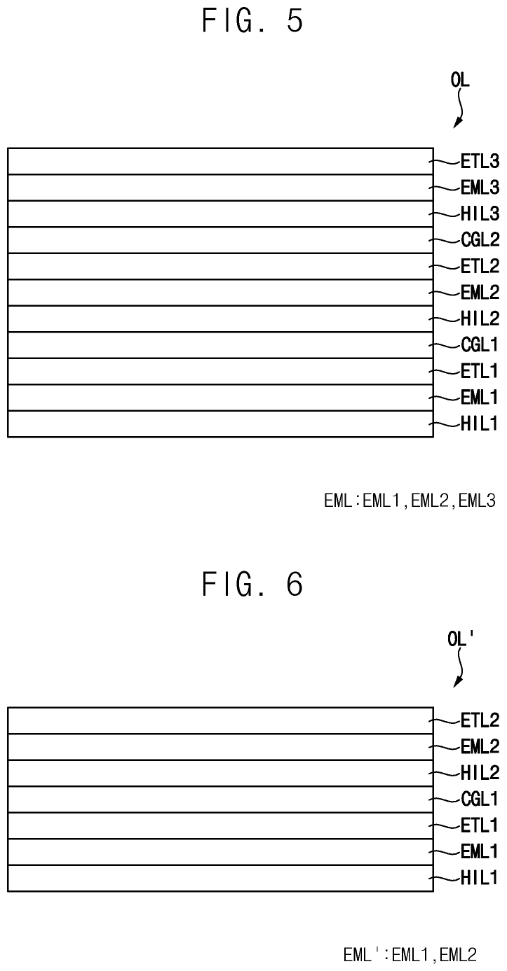

FIG. 4 is a cross-sectional view taken along the line II-II′ of FIG. 1. FIG. 5 is a view illustrating an organic layer according to one or more embodiments of FIG. 4.

Referring to FIGS. 1, 2, 4, and 5, the display device 1 according to one or more embodiments of the disclosure may include a substrate SUB, a planarization layer PNL, the light-emitting diode LD, an encapsulation layer TFE, the color filter layer CF, an overcoat layer OC, a cover window WIN, and a polarizing layer POL.

The substrate SUB may include various materials capable of supporting structures located on the substrate SUB. For example, the substrate SUB may include glass, plastic, or the like. These may be used alone or in combination with each other.

The substrate SUB may include a base substrate BSUB and a plurality of pixel circuit parts PXC.

A plurality of grooves may be defined in the base substrate BSUB. The pixel circuit parts PXC may be accommodated in the grooves, respectively.

Each of the plurality of pixel circuit parts PXC may include at least a transistor. In addition, each of the plurality of pixel circuit parts PXC may further include at least a capacitor.

The planarization layer PNL may include an insulating material. For example, the planarization layer PNL may include silicon oxide (SiO₂), silicon nitride (SiNₓ), silicon oxynitride (SiON), or the like. Accordingly, the planarization layer PNL may insulate the substrate SUB from a first electrode EL1 to be described later.

The planarization layer PNL may be located on the substrate SUB. A top surface of the planarization layer PNL may be flat. The substrate SUB may be a silicon wafer. A circuit structure or the like may be located on the silicon wafer. Accordingly, a top surface of the silicon wafer might not be flat. As the planarization layer PNL is located on the substrate SUB, the light-emitting diode LD described later may be located on the flat surface.

The light-emitting diode LD may include the first electrode EL1, an organic material layer OL, and a second electrode EL2. For example, the first electrode EL1 is located on the planarization layer PNL, the organic material layer OL is located on the first electrode EL1, and the second electrode EL2 is located on the organic material layer OL.

The first electrode EL1 may be electrically connected to the plurality of pixel circuit parts PXC. The first electrode EL1 may be electrically connected to the plurality of pixel circuit parts PXC through a via hole defined in the planarization layer PNL. The first electrode EL1 may receive a driving current from the transistor included in the plurality of pixel circuit parts PXC.

In one or more embodiments, the first electrode EL1 may be an anode. For example, the first electrode EL1 may receive an anode voltage from the transistor. The first electrode EL1 may include a conductive material. For example, the first electrode EL1 may include a metal, an alloy, a conductive metal oxide, a transparent conductive material, or the like. For example, the first electrode EL1 may include ITO, IZO, ZnO, In₂O₃, or the like. These may be used alone or in combination with each other. However, the disclosure is not limited thereto. The first electrode may also be a cathode.

The organic material layer OL may include a light-emitting layer EML and a functional layer.

The light-emitting layer EML may include an organic material that emits light of a corresponding color (e.g., a predetermined color).

The functional layer may assist light emission of the light-emitting layer EML. Examples of the functional layer may include a hole transport layer, a hole injection layer, an electron transport layer, an electron injection layer, or the like.

In one or more embodiments, the organic material layer OL may have a tandem structure. For example, the organic material layer OL may include a first hole injection layer HIL1, a first light-emitting layer EML1, a first electron transport layer ETL1, a first charge generation layer CGL1, a second hole injection layer HIL2, a second light-emitting layer EML2, a second electron transport layer ETL2, a second charge generation layer CGL2, a third hole injection layer HIL3, a third light-emitting layer EML3, and a third electron transport layer ETL3. However, the disclosure is not limited thereto. The functional layers may be omitted.

The organic material layer OL may include the plurality of light-emitting layers EML1, EML2, and EML3. Accordingly, the white light may be emitted from the light-emitting diode LD. However, the disclosure is not limited thereto. A stacking order, a type of the stacked layer may be changed.

In one or more embodiments, the second electrode EL2 may be located on the organic material layer OL. For example, the second electrode EL2 may extend along the first sub-pixel area SPX1, the second sub-pixel area SPX2, and the third sub-pixel area SPX3. That is, the second electrode EL2 may be integrally formed along the first sub-pixel area SPX1, the second sub-pixel area SPX2, and the third sub-pixel area SPX3. However, the disclosure is not limited thereto. The second electrode EL2 may be separately formed in each of the first sub-pixel area SPX1, the second sub-pixel area SPX2, and the third sub-pixel area SPX3.

In one or more embodiments, the second electrode EL2 may be the cathode. Light may be emitted from the light-emitting layer EML by a voltage difference between the first electrode EL1 and the second electrode EL2.

The second electrode EL2 may include a conductive material. For example, the second electrode EL2 may include a metal, an alloy, a conductive metal oxide, a transparent conductive material, or the like. For example, the second electrode EL2 may include Li, Ca, LiF/Ca, LiF/AI, Al, Ag, Mg, Ba, or the like. These may be used alone or in combination with each other. However, the disclosure is not limited thereto. The second electrode EL2 may be the anode.

The encapsulation layer TFE may be located on the light-emitting diode LD. For example, the encapsulation layer TFE may be located on the second electrode EL2. The encapsulation layer TFE may cover the light-emitting diode LD. Accordingly, the encapsulation layer TFE may reduce or prevent penetration of the foreign materials into the light-emitting diode LD. The foreign materials may be moisture, oxygen, or the like.

In one or more embodiments, the encapsulation layer TFE may have a single-layer structure. For example, the encapsulation layer TFE may be an inorganic layer having the single-layer structure. The encapsulation layer TFE including the inorganic layer may have high mechanical strength. For example, the inorganic layer may include silicon nitride, silicon oxynitride, or the like. These may be used alone or in combination with each other.

For another example, the encapsulation layer TFE may be an organic layer having the single-layer structure. For example, the organic layer may include acrylate. An upper surface of the encapsulation layer TFE including the organic layer may be flat.

In one or more other embodiments, the encapsulation layer TFE may have the multi-layer structure. For example, the encapsulation layer TFE may include at least an inorganic layer and at least an organic layer. For example, the encapsulation layer TFE may include a first inorganic layer, an organic layer, and a second inorganic layer. For example, the encapsulation layer TFE may have a structure in which the first inorganic layer, the organic layer, and the second inorganic layer are sequentially stacked. As the encapsulation layer TFE has the multi-layer structure, sealing property (e.g., a property of protecting the light-emitting diode LD from the foreign material) may be increased.

In one or more embodiments, the color filter layer CF may be located on the encapsulation layer TFE. In this case, the light-emitting diode LD may be a white organic light-emitting diode for emitting the white light. The white light emitted from the light-emitting diode LD may be converted into the light of various colors by passing through the color filter layer CF.

For example, the color filter layer CF may include a first color filter, a second color filter, and a third color filter. The first color filter may overlap the first sub-pixel region SPX1. The first color filter may transmit the second light among the first light emitted from the light-emitting layer EML, and cut (e.g., absorb, reduce, or block) the third light and the fourth light. For example, the red light may pass the first color filter. On the other hand, the blue light and the green light may be cut while passing through the first color filter.

The second color filter may overlap the second sub-pixel region SPX2. The second color filter may transmit the third light among the first light emitted from the light-emitting layer EML, and may cut (absorb, reduce, or block) the second light and the fourth light.

The third color filter may overlap the third sub-pixel region SPX3. The third color filter may transmit the fourth light among the first light emitted from the light-emitting layer EML, and may cut (absorb, reduce, or block) the second light and the third light.

However, the disclosure is not limited thereto. For example, the first color filter may partially overlap the first sub-pixel area SPX1 and the second sub-pixel area SPX2. The second color filter may partially overlap the second sub-pixel area SPX2 and the third sub-pixel area SPX3. The third color filter may overlap the third sub-pixel area SPX3 and a portion of a pixel area adjacent to the third sub-pixel area SPX3.

In one or more other embodiments, the color filter layer CF may be omitted. In this case, the light-emitting diode LD may include patterned light-emitting layers. The light-emitting layers may include light-emitting materials for emitting light of different respective colors. For example, the light-emitting layers may include a red light-emitting layer, a green light-emitting layer, and a blue light-emitting layer. The light-emitting layers may be formed by patterning a material forming a color filter.

A micro-lens array MLA may be located on the color filter layer CF. When the color filter layer CF is omitted, the micro-lens array MLA may be located on the light-emitting diode LD. For example, the micro-lens array MLA may be located on the second electrode EL2.

The micro-lens array MLA may include a plurality of lenses. Each of the lenses included in the micro-lens array MLA may extract, refract, or scatter light. In one or more embodiments, the lenses may overlap the sub-pixel regions SPX1, SPX2, and SPX3, respectively. In one or more other embodiments, a plurality of lenses may be located in each of the sub-pixel regions SPX1, SPX2, and SPX3. In one or more other embodiments, the micro-lens array MLA may be omitted.

The overcoat layer OC may planarize a top surface of a layer located under the overcoat layer OC (e.g., the color filter layer CF), and may cover the micro-lens array MLA. In one or more embodiments, the overcoat layer OC may include an inorganic insulating material. For example, the overcoat layer OC may include silicon oxide (SiO₂), silicon nitride (SiNₓ), silicon oxynitride (SiON), aluminum oxide (Al₂O₃), titanium dioxide (TiO₂), tantalum pentoxide (Ta₂O₅), hafnium oxide (HfO₂), zirconium dioxide (ZrO₂), or the like. These may be used alone or in combination with each other.

In one or more other embodiments, the overcoat layer OC may include an organic insulating material. For example, the overcoat layer OC may include an acryl-based polymer, an imide-based polymer, an aryl ether-based polymer, an amide-based polymer, a fluorine-based polymer, a p-xylene-based polymer, a vinyl alcohol-based polymer, or the like. These may be used alone or in combination with each other.

The overcoat layer OC may have a multi-layer structure. In this case, the overcoat layer OC may be configured such that a layer including the inorganic insulating material and/or a layer including the organic insulating material are alternately stacked. Alternatively, the overcoat layer OC may have the multi-layer structure in which only layers including materials having high transmittances are stacked in consideration of luminous efficiency. However, the disclosure is not limited thereto. Alternatively, the overcoat layer OC may have a single-layer structure or may be omitted.

In one or more embodiments, the cover window WIN may be located on the overcoat layer OC. The cover window WIN may protect the display panel. In one or more embodiments, the cover window WIN may include glass. The glass may have a flat plate shape. Alternatively, the glass may have a 2D shape in which an edge portion is bent, or a 3D shape in which an overall shape is bent.

In one or more other embodiments, the cover window WIN may include plastic. A display device 1 including the plastic may be lighter than a display device including the glass, and stronger against an impact than the display device including the glass.

However, the disclosure is not limited thereto, and the cover window WIN may include colorless PI, ultra-thin glass, or the like. Alternatively, the cover window WIN may be omitted.

In one or more embodiments, the polarizing layer POL may be located on the overcoat layer OC. The polarizing layer POL may reduce external light reflection of the display device 1.

In one or more other embodiments, the polarizing layer POL may be omitted. In this case, the color filter layer CF may reduce the external light reflection. When the polarizing layer POL is omitted from the display device 1, a thickness of the display device 1 may be less, and a light transmittance of the display device 1 may be improved.

FIG. 6 is a view illustrating the organic material layer according to one or more other embodiments of FIG. 4.

The organic material layer OL′ of FIG. 6 may differ from the organic material layer OL of FIG. 5 only in the type of stacked layer and the stacked structure.

Referring to FIGS. 5 and 6, the organic material layers OL and OL′ may have a tandem structure. The tandem structure may include a plurality of light-emitting layers EML or EML′.

As shown in FIG. 5, the organic material layer OL according to one or more embodiments may have a structure in which the first hole injection layer HIL1, the first light-emitting layer EML1, the first electron transport layer ETL1, the first charge generation layer CGL1, the second hole injection layer HIL2, the second light-emitting layer EML2, the second electron transport layer ETL2, the second charge generation layer CGL2, the third hole injection layer HIL3, the third light-emitting layer EML3, and a third electron transport layer ETL3 are sequentially stacked.

As shown in FIG. 6, the organic material layer OL′ according to one or more other embodiments may have a structure in which the first hole injection layer HIL1, the first light-emitting layer EML1, the first electron transport layer ETL1, the first charge generation layer CGL1, the second hole injection layer HIL2, the second light-emitting layer EML2, and the second electron transport layer ETL2 are sequentially stacked. However, the disclosure is not limited thereto, and the functional layers may be omitted.

The plurality of light-emitting layers EML1 and EML2 may emit light of different colors, respectively. For example, the first light-emitting layer EML1 may emit the yellow light, and the second light-emitting layer EML2 may emit the blue light. Accordingly, the white light may be emitted from the light emitting diode LD. However, the disclosure is not limited thereto. The stacking order or the types of stacked layers may be changed.

FIG. 7 is a cross-sectional view taken along the line III-III′ of FIG. 1. FIGS. 8, 9, and 10 are enlarged cross-sectional views illustrating a crack detection line included in the display device of FIG. 1.

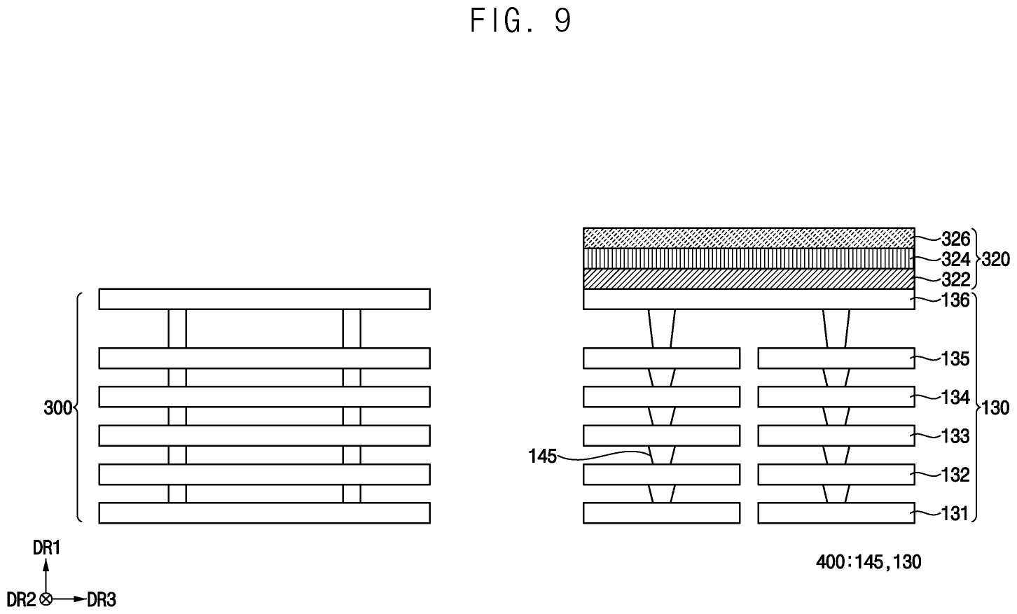

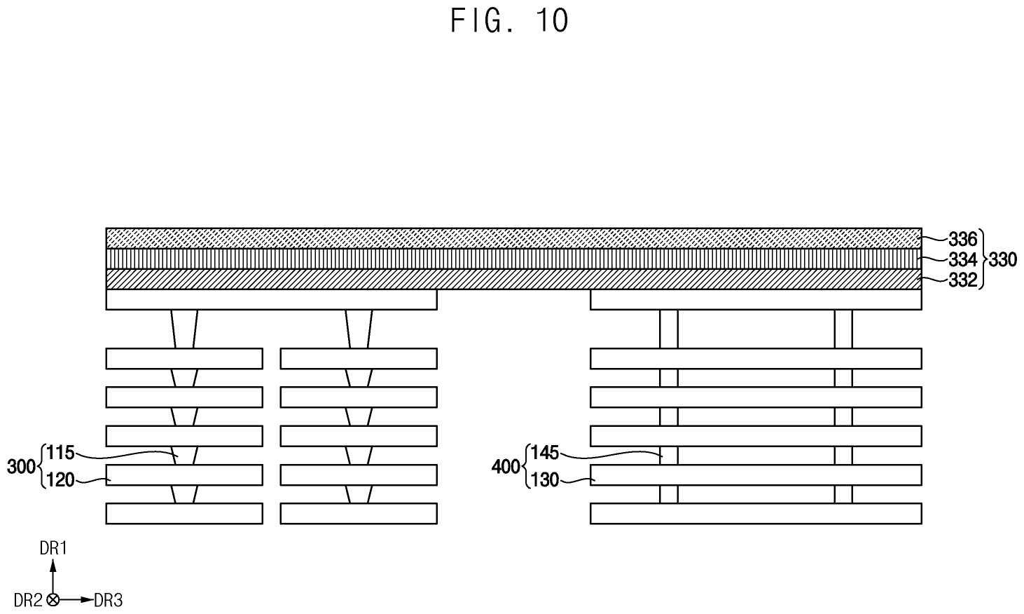

For example, FIG. 8 is a view illustrating a crack detection line 310 according to first embodiments. FIG. 9 is a view illustrating a crack detection line 320 according to second embodiments. FIG. 10 is a view illustrating a crack detection line 330 according to third embodiments.

Referring to FIGS. 1, 7, and 8, the display device 1 according to one or more embodiments of the disclosure may include a blocking structure SE and the crack detection line 310.

The blocking structure SE may be located on the substrate in the peripheral region PA. The blocking structure SE may include a first blocking layer 300 and a second blocking layer 400.

The first blocking layer 300 may be adjacent to the guard ring 200 in the third direction DR3 (or in the direction opposite to the third direction DR3) and spaced apart from the chip 100. The first blocking layer 300 may also be referred to as a crack stop layer (CSL).

The first blocking layer 300 may include a plurality of line layers 120 and a plurality of vias 115.

The plurality of line layers 120 may include a first line layer 121, a second line layer 122, a third line layer 123, a fourth line layer 124, a fifth line layer 125, and a sixth line layer 126. For example, the second line layer 122 may be located on the first line layer 121, the third line layer 123 may be located on the second line layer 122, the fourth line layer 124 may be located on the third line layer 123, the fifth line layer 125 may be located on the fourth line layer 124, and the sixth line layer 126 may be located on the fifth line layer 125.

The plurality of line layers 120 may include a metal material. For example, the first line layer 121, the second line layer 122, the third line layer 123, the fourth line layer 124, the fifth line layer 125, and the sixth line layer 126 may include a same metal material. For example, each of the first line layer 121, the second line layer 122, the third line layer 123, the fourth line layer 124, the fifth line layer 125, and the sixth line layer 126 may include aluminum (Al), copper (Cu), or the like. These may be used alone or in combination with each other. However, the disclosure is not limited thereto. For example, each of the first line layer 121, the second line layer 122, the third line layer 123, the fourth line layer 124, the fifth line layer 125, and the sixth line layer 126 may include different materials from each other.

In FIG. 8, it has been described that the plurality of line layers 120 may include six metal layers, however, the disclosure is not limited thereto. For example, the plurality of line layers 120 may include two, three, four, five, or more than six metal layers.

An interlayer insulating layer may be located between the plurality of line layers 120. The interlayer insulating layer may be an inter metal dielectric (IMD) having a low dielectric constant (low-k).

The metal-insulating layer may be located between the plurality of line layers 120 and 130 to be described later, and may insulate the metal lines from each other. Accordingly, the metal-insulating layer may reduce or prevent the likelihood of a short between the metal lines.

The plurality of vias 115 may be defined in the metal-insulating layer. Each of the plurality of vias 115 may electrically connect the plurality of line layers 120. For example, each of the plurality of vias 115 may be located between the first line layer 121 and the second line layer 122, between the second line layer 122 and the third line layer 123, between the third line layer 123 and the fourth line layer 124, between the fourth line layer 124 and the fifth line layer 125, and between the fifth line layer 125 and the sixth line layer 126.

Each of the plurality of vias 115 may include a chemical-resistant metal material. For example, each of the plurality of vias 115 may include tungsten (W) or the like. Each of the chemical-resistant metal materials may be used alone or in combination with each other.

The number of vias 115 may also vary according to the number of line layers 120. In addition, the type of material included in the plurality of vias 115 may vary according to the material included in the plurality of line layers 120.

The first blocking layer 300 may block moisture from entering toward the chip 100 through the scribing line SL during a back grinding process.

The back grinding process may refer to a process of grinding a back surface of the wafer. For example, a protective film may be attached to a front surface of the wafer. The protective film may reduce or prevent damage to an electronic circuit located on the front surface of the wafer while the back grinding process is in progress. Thereafter, the back surface of the wafer may be removed to have a corresponding thickness (e.g., a predetermined thickness). After the back grinding process is completed, the protective film may be removed from the wafer. Through the back grinding process, the thickness of the wafer may be reduced.

The scribing line SL may be positioned adjacent to the second blocking layer 400 in the third direction DR3 (or in a direction opposite to the third direction DR3).

The scribing line SL may refer to a groove defined on the wafer. For example, the scribing line SL may be defined adjacent to the chip 100. In the cross-sectional view, the scribing line SL may be formed to a depth of about half of the thickness of the wafer. As the scribing line SL is defined on the wafer, separating the wafer into the individual chips 100 may be facilitated.

A detailed description of the structure of the second blocking layer 400 will be described later with reference to FIG. 9.

In one or more embodiments, the crack detection line 310 may be located on the first blocking layer 300. The crack detection line 310 may also be referred to as a module crack detection (MCD) line.

The crack detection line 310 may apply voltage to pixels (e.g., the plurality of pixels PX of FIG. 1). When the crack occurs in an outer portion of the panel (e.g., the peripheral region PA of FIG. 1), a bright line may appear in the pixel while resistance increases. Through this, the crack detection line 310 may detect the crack. However, the disclosure is not limited thereto. The crack detection line 310 may detect the crack in various ways. For example, the crack detection line 310 may detect an abnormal resistance value, and may compare the abnormal resistance value with a reference value stored in a memory to determine whether the crack occurs. Next, when it is determined that the crack has occurred, a crack generation signal may be generated. Accordingly, minute cracks that are otherwise difficult to observe may be detected in advance, so that manufacturing may improve.

In one or more embodiments, the crack detection line 310 may include a first metal layer 312, a second metal layer 314, and a third metal layer 316. For example, the first metal layer 312 may be located on the first blocking layer 300. The second metal layer 314 may be located on the first metal layer 312. The third metal layer 316 may be located on the second metal layer 314.

In one or more embodiments, the first metal layer 312 may include a reflective metal material. For example, the first metal layer 312 may include silver (Ag), aluminum (Al), or the like. These may be used alone or in combination with each other. The first metal layer 312 may serve as a resonance reflective layer.

In one or more embodiments, the second metal layer 314 may include a transparent conductive material or a translucent conductive material. For example, the second metal layer 314 may include indium tin oxide (ITO), indium zinc oxide (IZO), or the like. These may be used alone or in combination with each other. In one or more embodiments, the second metal layer 314 may be located on a same layer as the anode electrode (e.g., the second electrode EL2 of FIG. 4).

In one or more embodiments, the third metal layer 316 may be located on the second metal layer 314 and may include a chemical-resistant metal material. For example, the third metal layer 316 may include titanium (Ti), tantalum (Ta), or the like. These may be used alone or in combination with each other.

The third metal layer 316 may reduce or prevent the likelihood of the second metal layer 314 being damaged in a subsequent process. For example, the anode electrode may have a thin thickness. Accordingly, the anode may be damaged in the process of forming the color filter layer (e.g., the color filter layer CF of FIG. 4). The third metal layer 316 may cover the anode to reduce or prevent the likelihood of the anode being damaged in the process of forming the color filter layer.

In one or more other embodiments, the third metal layer 316 may be omitted. For example, in the micro-display, the light-emitting layer (e.g., the light-emitting layer EML of FIG. 5 and the light-emitting layer EML′ of FIG. 6) may be formed by patterning the color filter material. In this case, because the color filter may be omitted, the third metal layer 316 for reducing or preventing the likelihood of the anode being damaged in the process of forming the color filter layer may also be omitted.

Referring to FIGS. 1, 7 and 9, the display device 1 according to second embodiments of the disclosure may include the blocking structure SE and the crack detection line 320.

The blocking structure SE may be located on the substrate in the peripheral region PA. The blocking structure SE may include a first blocking layer 300 and a second blocking layer 400.

The second blocking layer 400 may be adjacent to the first blocking layer 300 in the third direction DR3 (or in the direction opposite to the third direction DR3), and may be spaced apart from the guard ring 200. The second blocking layer 400 may also be referred to as a moisture oxidation blocking (MOB) layer. The second blocking layer 400 may include a plurality of line layers 130 and a plurality of vias 145.

The plurality of line layers 130 may include a first line layer 131, a second line layer 132, a third line layer 133, a fourth line layer 134, a fifth line layer 135, and a sixth line layer 136. For example, the second line layer 132 may be located on the first line layer 131, the third line layer 133 may be located on the second line layer 132, the fourth line layer 134 may be located on the third line layer 133, the fifth line layer 135 may be located on the fourth line layer 134, and the sixth line layer 136 may be located on the fifth line layer 135.

The plurality of line layers 130 may include a metal material. For example, the first line layer 131, the second line layer 132, the third line layer 133, the fourth line layer 134, the fifth line layer 135, and the sixth line layer 136 may include a same metal material. For example, each of the first line layer 131, the second line layer 132, the third line layer 133, the fourth line layer 134, the fifth line layer 135, and the sixth line layer 136 may include aluminum (Al), copper (Cu), or the like. These may be used alone or in combination with each other. However, the disclosure is not limited thereto. For example, each of the first line layer 131, the second line layer 132, the third line layer 133, the fourth line layer 134, the fifth line layer 135, and the sixth line layer 136 may include different materials from each other.

In FIG. 9, it has been described that the plurality of line layers 130 may include six metal layers, however, the disclosure is not limited thereto. For example, the plurality of line layers 130 may include two, three, four, five, or more than six metal layers.

The metal-insulating layer may be located between the plurality of line layers 130. The plurality of vias 145 may be defined in the metal-insulating layer. Each of the plurality of vias 145 may electrically connect the plurality of line layers 130. For example, the vias 145 may be respectively located between the first line layer 131 and the second line layer 132, between the second line layer 132 and the third line layer 133, between the third line layer 133 and the fourth line layer 134, between the fourth line layer 134 and the fifth line layer 135, and between the fifth line layer 135 and the sixth line layer 136.

Each of the plurality of vias 145 may include the chemical-resistant metal material. For example, each of the plurality of vias 145 may include tungsten (W) or the like. Each of the chemical-resistant metal materials may be used alone or in combination with each other.

The number of vias 145 may also vary according to the number of line layers 130. In addition, the type of material included in the plurality of vias 145 may vary according to the material included in the plurality of line layers 130.

The second blocking layer 400 may reduce or prevent the likelihood of a crack propagating in the metal-insulating layer during sawing and packaging processes. The packaging process may mean a process of dividing the wafer into the individual semiconductor chips.

In one or more embodiments, the crack detection line 320 may be located on the second blocking layer 400. In one or more embodiments, the crack detection line 320 may include a first metal layer 322, a second metal layer 324, and a third metal layer 326. For example, the first metal layer 322 may be located on the second blocking layer 400. The second metal layer 324 may be located on the first metal layer 322. The third metal layer 326 may be located on the second metal layer 324.

In one or more embodiments, the first metal layer 322 may include the reflective metal material. For example, the first metal layer 322 may include silver (Ag), aluminum (Al), or the like. These may be used alone or in combination with each other. The first metal layer 322 may serve as the resonance reflective layer.

In one or more embodiments, the second metal layer 324 may include the transparent conductive material or a translucent conductive material. For example, the second metal layer 324 may include indium tin oxide (ITO), indium zinc oxide (IZO), or the like. These may be used alone or in combination with each other. In one or more embodiments, the second metal layer 324 may be located on the same layer as the anode electrode (e.g., the second electrode EL2 of FIG. 4).

In one or more embodiments, the third metal layer 326 may be located on the second metal layer 324 and may include the chemical-resistant metal material. For example, the third metal layer 326 may include titanium (Ti), tantalum (Ta), or the like. These may be used alone or in combination with each other.

In one or more other embodiments, the third metal layer 326 may be omitted. In this case, the display device 1 might not also include the color filter layer (e.g., the color filter layer CF of FIG. 4).

Referring to FIGS. 1, 7 and 10, the display device 1 according to third embodiments of the disclosure may include the blocking structure SE and the crack detection line 330.

The blocking structure SE may be located on the substrate in the peripheral region PA. The blocking structure SE may include the first blocking layer 300 and the second blocking layer 400.

The second blocking layer 400 may be adjacent to the first blocking layer 300 in the third direction DR3 (or in the direction opposite to the third direction DR3) and spaced apart from the guard ring 200. The second blocking layer 400 may also be referred to as the moisture oxidation blocking (MOB) layer.

In one or more embodiments, the crack detection line 330 may be located on both the first blocking layer 300 and the second blocking layer 400.

In one or more embodiments, the crack detection line 330 may include a first metal layer 332, a second metal layer 334, and a third metal layer 336. For example, the first metal layer 332 may be located on the second blocking layer 400. The second metal layer 334 may be located on the first metal layer 332. The third metal layer 336 may be located on the second metal layer 334.

In one or more embodiments, the first metal layer 332 may include the reflective metal material. For example, the first metal layer 332 may include silver (Ag), aluminum (Al), or the like. These may be used alone or in combination with each other. The first metal layer 332 may serve as the resonance reflective layer.

In one or more embodiments, the second metal layer 334 may include the transparent conductive material or a translucent conductive material. For example, the second metal layer 334 may include indium tin oxide (ITO), indium zinc oxide (IZO), or the like. These may be used alone or in combination with each other. In one or more embodiments, the second metal layer 334 may be located on the same layer as the anode electrode (e.g., the second electrode EL2 of FIG. 4).

In one or more embodiments, the third metal layer 336 may be located on the second metal layer 334 and may include the chemical-resistant metal material. For example, the third metal layer 336 may include titanium (Ti), tantalum (Ta), or the like. These may be used alone or in combination with each other.

In one or more other embodiments, the third metal layer 336 may be omitted. In this case, the display device 1 might not also include the color filter layer (e.g., the color filter layer CF of FIG. 4).

The display device according to a comparative example might not include the crack detection line 310, 320, or 330. In this case, the display device according to the comparative example might not detect the crack. Moisture or the like may penetrate into the display device according to the comparative example through the crack. Accordingly, the display device according to the comparative example might not be driven, or defects, such as dark spots may occur.

The display device 1 according to one or more embodiments may include the crack detection line 310, 320, or 330 to detect the crack. Accordingly, a defect rate of the display device may be improved.

The display device 1 may include various components connected to the crack detection line 310, 320, or 330. For example, the display device 1 may further include a lighting circuit. The lighting circuit may be connected to the crack detection line 310, 320, or 330 to output a signal so that some pixels emit light when the crack is detected.

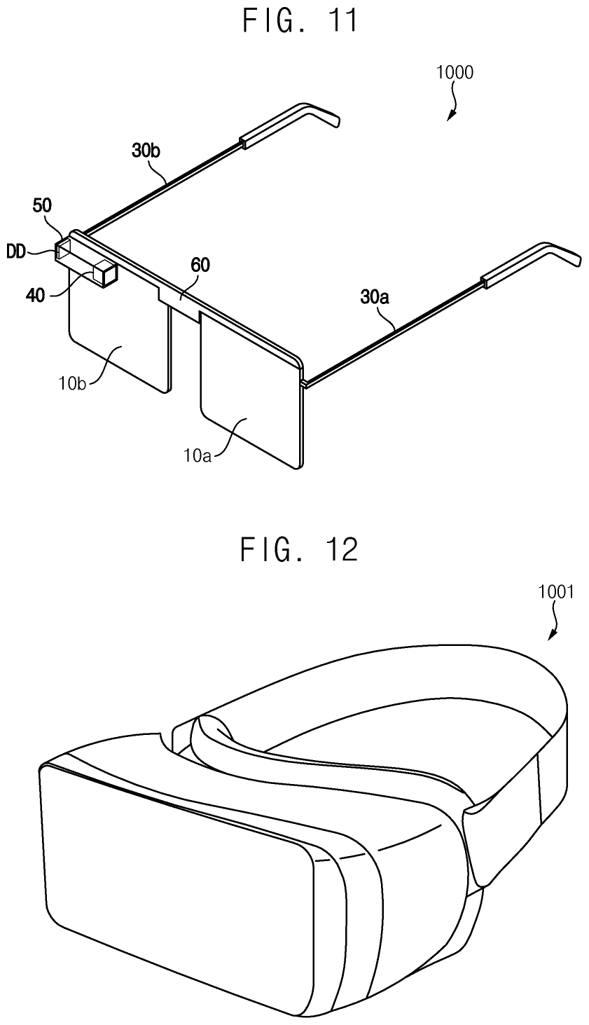

FIG. 11 is view illustrating one or more embodiments in which the display device of FIG. 1 is implemented as smart glasses. FIG. 12 is a view illustrating one or more embodiments in which the display device of FIG. 1 is implemented as a head mounted display device.

Referring to FIGS. 11 and 12, the display device 1 may be implemented as virtual reality devices 1000 and 1001. For example, the virtual reality device 1000 of FIG. 11 may be smart glasses, and the virtual reality device 1001 of FIG. 12 may be a head mounted display (HMD).

In one or more embodiments, the virtual reality device 1000 may include a display device DD, a plurality of lenses 10a and 10b, support frames 30a and 30b, and a housing 50. The display device DD may be the display device 1 of FIG. 1. A reflector 40 and the display device DD may be located in the housing 50. The image provided by the display device DD may be reflected by the reflector 40, and the image reflected by the reflector 40 may be provided to both eyes of the user.

The housing 50 may be located outside the virtual reality device 1000. In FIG. 11, it is shown that the housing 50 is adjacent to one of support frames 30a and 30b, however, the disclosure is not limited thereto. For example, the housing 50 may be in a center of the virtual reality device 1000.

In one or more other embodiments, the virtual reality device 1001 might not include the support frames 30a and 30b. In this case, the virtual reality device 1001 may further include a head-mounted band.

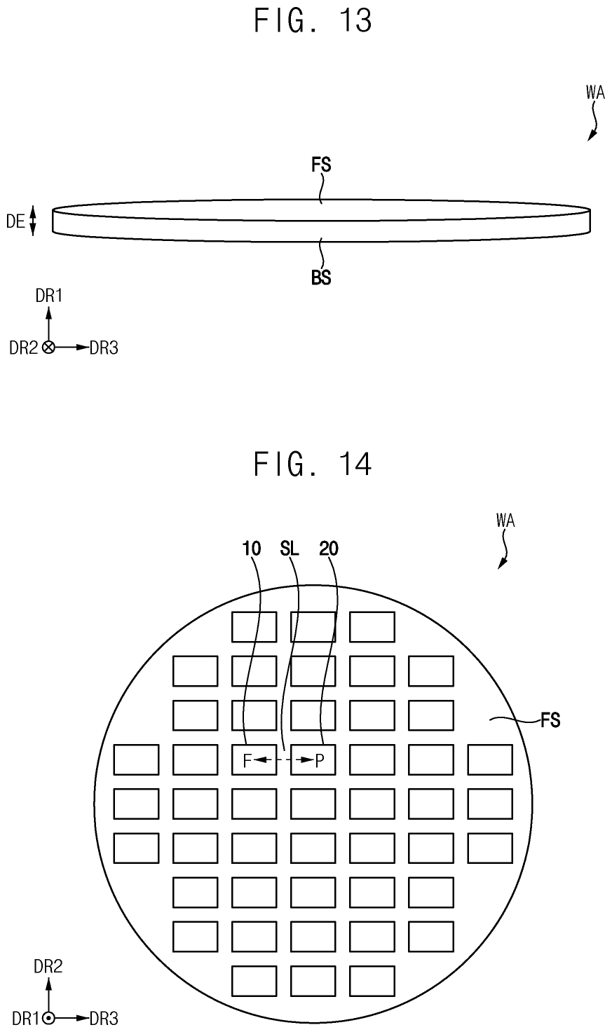

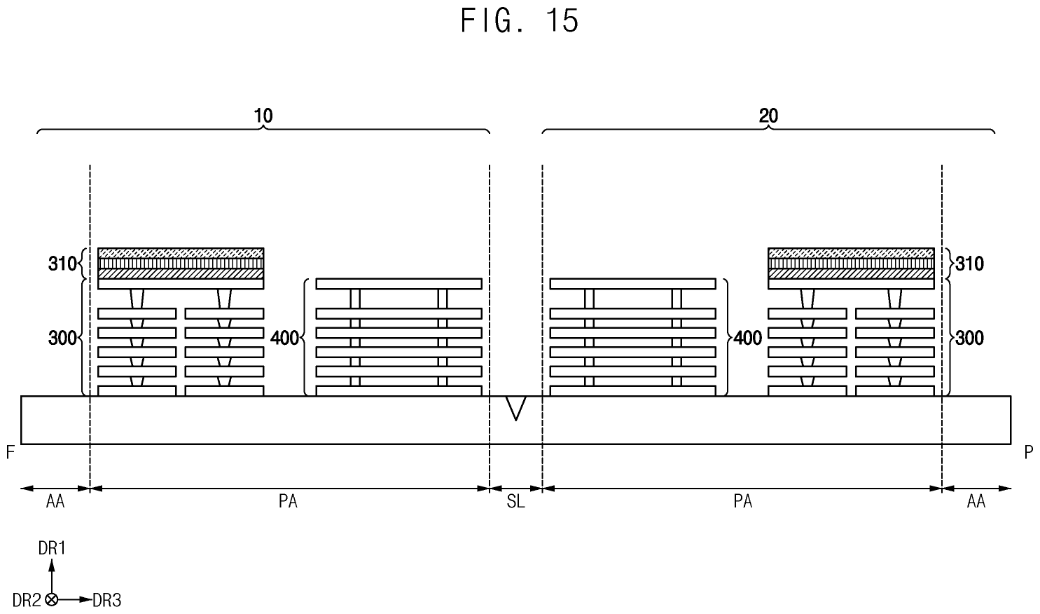

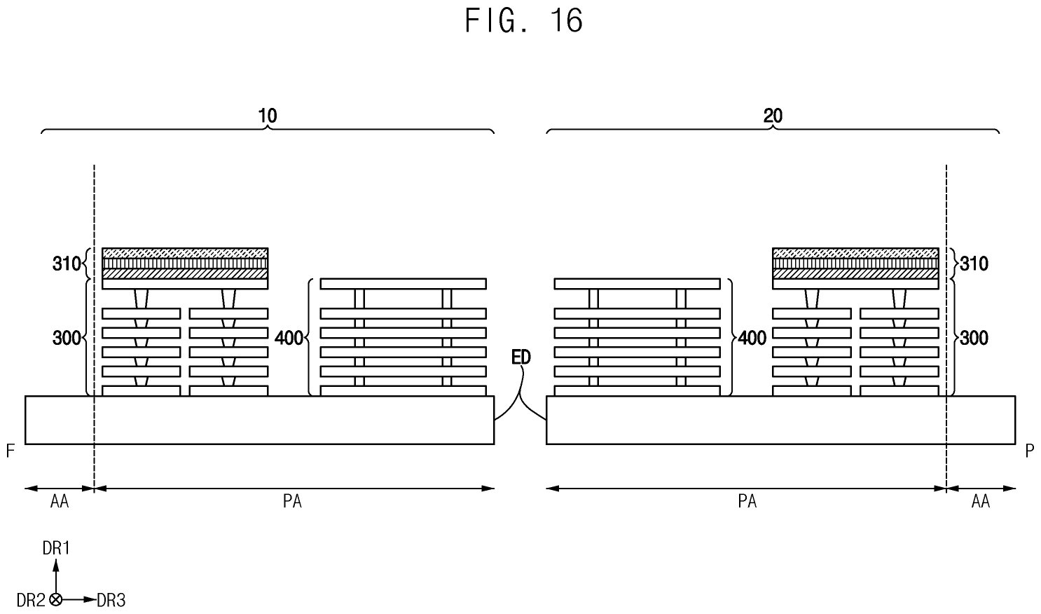

FIGS. 13, 14, 15, 16, 17, and 18 are views illustrating a method of manufacturing the display device of FIG. 1, wherein FIGS. 15, 16, 17, and 18 are cross-sectional views taken along the line F-P of FIG. 14.

Hereinafter, redundant descriptions corresponding to the display device 1 described above with reference to FIGS. 1, 2, 3, 4, 5, 6, 7, 8, 9, 10, 11, and 12 will be omitted or simplified.

Referring to FIGS. 1, 13, and 14, the method of manufacturing the display device according to one or more embodiments may include forming the substrate. The substrate may be formed of a wafer WA.

The wafer WA may include silicon. For example, the wafer WA may be a monocrystalline silicon wafer, a polycrystalline silicon wafer, or an amorphous silicon wafer. The wafer WA may include a front surface FS and a back surface BS. A semiconductor pattern may be formed on the front surface FS of the wafer WA. For example, the substrate may be the silicon semiconductor substrate formed through a complementary metal oxide semiconductor (CMOS) process.

A layer including the light-emitting diode (e.g., the light-emitting diode LD of FIG. 4) may be located on the substrate. For example, the display device 1 may be an OLED on silicon in which an organic light-emitting diode is located on the silicon semiconductor substrate.

A thickness DE of the wafer WA may be controlled through the back grinding process. For example, as the back surface BS is removed or reduced in the back grinding process, the thickness DE of the wafer WA may be reduced.

Referring to FIGS. 13, 14, and 15, the method of manufacturing the display device may include forming the crack detection line 310.

The scribing line SL may be formed on the wafer WA. The scribing line SL may be positioned between individual chips 10 and 20. The scribing line SL may be formed to the depth of about half of the thickness DE of the wafer WA.

The blocking structure (e.g., the blocking structure SE of FIG. 7) may be formed on the wafer WA to reduce or prevent the likelihood of the crack occurring in a process of separating the wafer WA into the individual chips 10 and 20, respectively.

The blocking structure may include the first blocking layer 300 and the second blocking layer 400. For example, the first blocking layer 300 may reduce or prevent the likelihood of moisture penetrating toward the display region AA in the back grinding process. The second blocking layer 400 may be the structure for reducing or preventing the likelihood of the crack from propagating toward the display region AA during the process of separating the individual chips 10 and 20 along the scribing line SL.

The crack detection line 310 may be formed on the blocking structure to detect the crack generated in the process of separating the wafer WA into the individual chips 10 and 20, respectively.

Referring to FIG. 16, the crack detection line 310 may be formed on the first blocking layer 300. Accordingly, the crack detection line 310 may detect the crack generated in the peripheral region PA.

For example, the crack may occur in an edge portion ED separated into the individual chips 10 and 20. When the crack propagates to the display region AA, the display device might not be driven, or a defect, such as the dark spot, may occur.

The method of manufacturing the display device according to one or more embodiments of the disclosure may include forming the crack detection line 310 on the first blocking layer 300, so that the crack generated in the peripheral region PA adjacent to the display region AA may be detected.

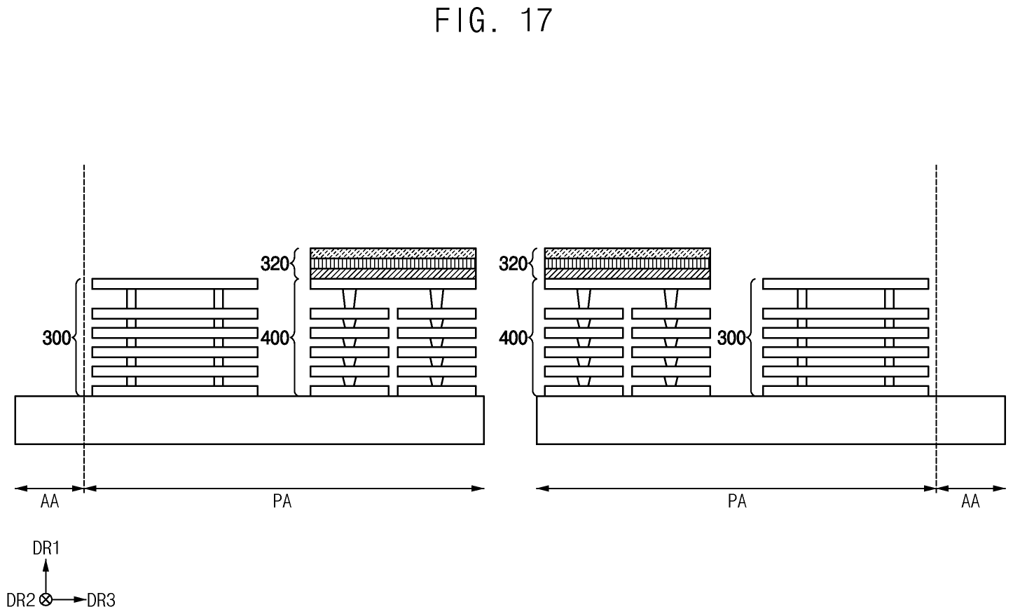

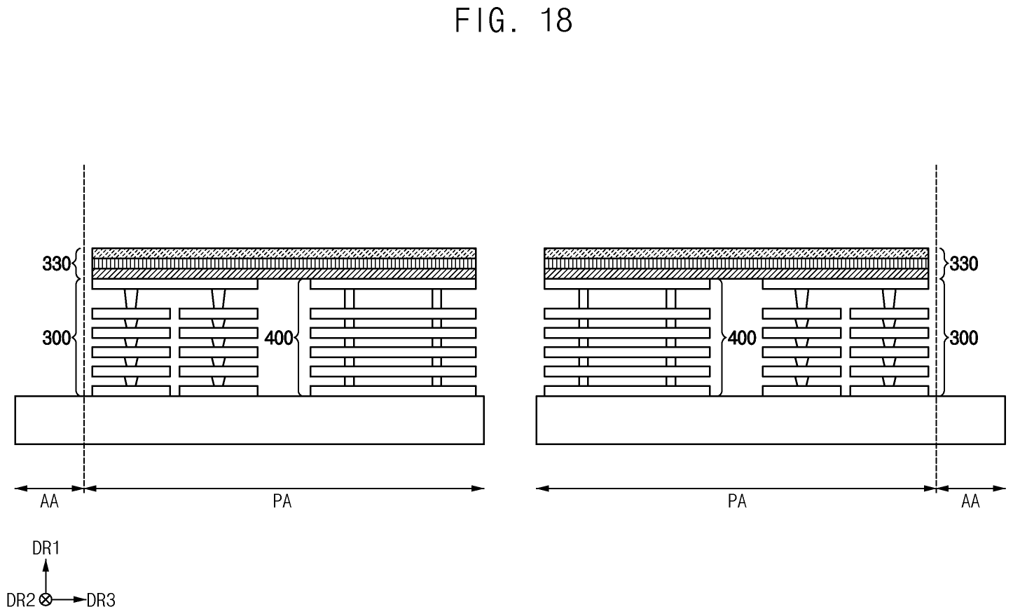

Referring to FIGS. 15 and 17, the method of manufacturing the display device may include forming the crack detection line 320 on the second blocking layer 400.

The second blocking layer 400 may be closer to the scribing line SL than the first blocking layer 300. Therefore, the crack detection line 320 located on the second blocking layer 400 may more easily detect the crack generated adjacent to the scribing line SL in the process of separating the chips into individual chips 10 and 20.

Referring to FIGS. 15 and 18, the method of manufacturing the display device may include forming the crack detection line 330 on both the first blocking layer 300 and the second blocking layer 400.

As the crack detection line 330 may be located on both the first blocking layer 300 and the second blocking layer 400, the crack generated in the peripheral area PA may be more accurately detected.

In the above, the crack detection line 310, 320, or 330 is illustrated as having a single line structure in the plan view (e.g., a plane defined by the second and third directions DR2 and DR3), however, the disclosure is not limited thereto. For example, the crack detection line 310, 320, or 330 may be plural (e.g., the crack detection line 310, 320, or 330 may have a multi-line structure

The disclosure of the display device and the method of manufacturing the display device may be applied to various electronic devices. For example, the disclosure may be applied to a display device included in a cell phone, a smart phone, a video phone, a smart pad, a smart watch, a tablet pc, a navigation for vehicle, television, a computer monitor, a notebook, a head mount display and/or the like and a method of manufacturing the display device.

Although the embodiments have been described with reference to the drawings, the illustrated embodiments are examples, and may be modified and changed by a person having ordinary knowledge in the relevant technical field without departing from the technical spirit described in the following claims, with functional equivalents thereof to be included therein.

1 what is claimed is:

1. A display device comprising:
a substrate comprising a semiconductor chip, and having a display region, and a peripheral region adjacent to the display region;
pixels above the substrate in the display region; and
a crack detection line above the substrate in the peripheral region.

2. The display device of claim 1, wherein the crack detection line has a multi-layer structure.

3. The display device of claim 2, wherein the crack detection line comprises:
a first metal layer; and
a second metal layer above the first metal layer.

4. The display device of claim 3, wherein the first metal layer comprises a reflective metal material, and
wherein the second metal layer comprises a transparent conductive material or a translucent conductive material.

5. The display device of claim 3, wherein the crack detection line further comprises a third metal layer above the second metal layer.

6. The display device of claim 5, wherein the third metal layer comprises a chemical-resistant metal material.

7. The display device of claim 1, wherein the substrate further comprises:
a first blocking layer in the peripheral region; and
a second blocking layer in the peripheral region adjacent to the first blocking layer.

8. The display device of claim 7, wherein the crack detection line is above the first blocking layer.

9. The display device of claim 7, wherein the crack detection line is above the second blocking layer.

10. The display device of claim 7, wherein the crack detection line is above both the first blocking layer and the second blocking layer.

11. A display device comprising:
a substrate having a display region, and a peripheral region adjacent to the display region, and having a width of about tens of micrometers or less;
pixels above the substrate in the display region; and
a crack detection line above the substrate in the peripheral region.

12. The display device of claim 11, wherein the crack detection line has a multi-layer structure.

13. The display device of claim 12, wherein the crack detection line comprises:
a first metal layer; and
a second metal layer above the first metal layer.

14. The display device of claim 13, wherein the first metal layer comprises a reflective metal material, and
wherein the second metal layer comprises a transparent conductive material or a translucent conductive material.

15. The display device of claim 13, wherein the crack detection line further comprises a third metal layer above the second metal layer.

16. The display device of claim 15, wherein the third metal layer comprises a chemical-resistant metal material.

17. The display device of claim 11, wherein the substrate further comprises:
a first blocking layer in the peripheral region; and
a second blocking layer in the peripheral region adjacent to the first blocking layer.

18. The display device of claim 17, wherein the crack detection line is above the first blocking layer.

19. The display device of claim 17, wherein the crack detection line is above the second blocking layer.

20. The display device of claim 17, wherein the crack detection line is above both the first blocking layer and the second blocking layer.
